(19) United States
(12) Patent Application Publication
(10) Pub. No.: US 2013/0309786 A1
(43) Pub. Date: Nov. 21, 2013

(54) METHOD FOR MANUFACTURING IMAGE SENSOR MODULE

(71) Applicant: SK HYNIX INC., Gyeonggi-do (KR)

(72) Inventor: Seung Taek YANG, Seoul (KR)

(73) Assignee: SK HYNIX INC., Gyeonggi-do (KR)

(21) Appl. No.: 13/948,596

(22) Filed: Jul. 23, 2013

Related U.S. Application Data
(62) Division of application No. 12/605,437, filed on Oct. 26, 2009.

(30) Foreign Application Priority Data
Aug. 10, 2009 (KR) 10-2009-0073508

(51) Int. Cl. H01L 21/66

(52) U.S. Cl. CPC H01L 22/14
USPC 438/17

(57) ABSTRACT

An image sensor module includes a semiconductor chip, a transparent substrate, and metal lines. The semiconductor chip includes image sensors disposed in an image sensor region, pads electrically connected to the image sensors and disposed in a peripheral region defined along a periphery of the image sensor region, and through-electrodes electrically connected to the pads. The transparent substrate has a groove defined by a surface covering the image sensors and the pads of the semiconductor chip. The metal lines are disposed on a lower surface of the semiconductor chip and are electrically connected to the through-electrodes.

### CROSS-REFERENCE TO RELATED APPLICATIONS

The present application claims priority to Korean patent application number 10-2009-0073508 filed on Aug. 10, 2009, which is incorporated herein by reference in its entirety.

### BACKGROUND OF THE INVENTION

The present invention relates to an image sensor module.

In general, an image sensor module is defined as a device for converting light as an analog signal into an electrical signal.

In developing an image sensor module it is desirable to obtain a high degree of resolution. A typical image sensor module is formed on a wafer and undergoes a packaging process. The image sensor includes semiconductor chips in which image sensors are formed, and glass substrates are disposed on the respective semiconductor chips.

When manufacturing image sensor modules glass substrates are inevitably disposed on defective semiconductor chips of a wafer as well as good semiconductor chips. The packaging process is then conducted for not only the good but also the defective semiconductor chips causing increased manufacturing cost.

Further, conventional image sensor modules utilize spacers placed along the periphery of a semiconductor chip to separate by a predetermined distance the semiconductor chip and the glass substrate. These spacers complicate the manufacturing process of an image sensor causing further increase in manufacturing cost.

Further, arranging a glass substrate directly on a semiconductor chip can be considered advantageous in that the size of the image sensor module can be more closely limited to the size of a semiconductor chip. However, in such a configuration light is likely to be incident on portions of the image sensor module aside from the image sensor leading to the presence of noise in the images obtained from the image sensors.

### BRIEF SUMMARY OF THE INVENTION

Embodiments of the present invention include an image sensor module which has a reduced thickness and volume, increased manufacturing yield, and which prevents unnecessary external light from being incident on image sensors and the resulting noise therefrom.

Further, embodiments of the present invention include methods for manufacturing the image sensor module.

In one embodiment of the present invention, an image sensor module comprises a semiconductor chip having image sensors disposed in an image sensor region, pads disposed in a peripheral region defined along a periphery of the image sensor region and electrically connected to the image sensors, and through-electrodes electrically connected to the pads; a transparent substrate having a groove covering the image sensors and pads of the semiconductor chip; and metal lines disposed on a lower surface of the semiconductor chip and electrically connected to the through-electrodes.

The groove may have a first groove which corresponds to the image sensor region and forms an inner surface spaced apart from the image sensors; and a second groove which receives the semiconductor chip.

A rear surface of the transparent substrate and the lower surface of the semiconductor chip may be flush with each other.

The metal lines may include extensions which extend from the lower surface of the semiconductor chip onto the rear surface of the transparent substrate.

The transparent substrate may comprise a transparent member having a shape and an area that correspond to those of the image sensor region; and a housing member possessing the substantial configuration of a cylinder which is open at front and rear ends thereof, having an inner surface on which the transparent member is fitted, and containing an opaque substance for intercepting light.

The transparent substrate may have a lens part formed on at least one of the inner surface and a front surface, opposite to the inner surface, of the transparent substrate.

The lens part may comprise at least one of a convex lens part and a concave lens part.

The transparent substrate may include a light intercepting member disposed on a portion of the transparent member which corresponds to the peripheral region.

The image sensor module may further comprise an adhesive member interposed between the transparent substrate and the semiconductor chip to couple the transparent substrate and the semiconductor chip to each other.

In another embodiment of the present invention, a method for manufacturing an image sensor module comprises the steps of manufacturing a semiconductor chip having image sensors formed in an image sensor region, pads disposed in a peripheral region defined along a periphery of the image sensor region and electrically connected to the image sensors, and through-electrodes electrically connected to the pads; forming a transparent substrate having a groove which faces the image sensors; coupling the transparent substrate and the semiconductor chip such that an inner surface of the transparent substrate formed due to defining of the groove and the image sensors face each other; and forming metal lines on a lower surface of the semiconductor chip to be electrically connected to the through-electrodes.

The step of manufacturing the semiconductor chip may comprise the steps of forming semiconductor chips on a wafer; sorting good and bad quality semiconductor chips by testing the semiconductor chips; and individualizing the semiconductor chips from the wafer and selecting the good quality semiconductor chips.

The step of forming the transparent substrate may comprise the steps of defining a first groove having a first area and a first depth that correspond to those of the image sensor region, on the transparent substrate; and defining a second groove having a second area that corresponds to an area of the semiconductor chip and a second depth that is shallower than the first depth, on the transparent substrate.

The first and second grooves may be defined through any one of an etching process for etching the transparent substrate, an extrusion process for extruding melted transparent substance using a mold, and a stamping process for stamping flowable transparent substance.

The step of forming the transparent substrate may comprise the steps of preparing a transparent member which corresponds to the image sensor region; and fastening the transparent member to an inner surface of a housing member which has the substantial configuration of a cylinder.

The housing member may be formed of light intercepting substance for intercepting light.

The step of forming the transparent substrate may further comprise the step of forming a light intercepting member in the peripheral region to intercept light incident on the peripheral region of the transparent substrate.

A rear surface of the transparent substrate and the lower surface of the semiconductor chip may be flush with each other.

The step of forming the metal lines may comprise the step of extending portions of the wiring lines from the lower surface of the semiconductor chip onto the rear surface of the transparent substrate.

The step of forming the transparent substrate may comprise the step of forming a lens part on at least one of the inner surface and a front surface, opposite to the inner surface, of the transparent substrate.

The method may further comprise the step of forming a lens part on at least one of the inner surface and a front surface, opposite to the inner surface, of the transparent substrate.

### BRIEF DESCRIPTION OF THE DRAWINGS

FIG. 1 is a cross-sectional view showing an image sensor module in accordance with an embodiment of the present invention.

FIG. 2 is a cross-sectional view showing an embodiment of the transparent substrate shown in FIG. 1.

FIG. 3 is a cross-sectional view showing an image sensor module in accordance with another embodiment of the present invention.

FIG. 4 is a cross-sectional view showing an image sensor module in accordance with another embodiment of the present invention.

FIG. 5 is a cross-sectional view showing an image sensor module in accordance with another embodiment of the present invention.

FIGS. 6 through 12 are cross-sectional views showing a method for manufacturing an image sensor module in accordance with another embodiment of the present invention.

### DESCRIPTION OF SPECIFIC EMBODIMENTS

It is understood herein that the drawings are not necessarily to scale and in some instances proportions may have been exaggerated in order to more clearly depict certain features of the invention.

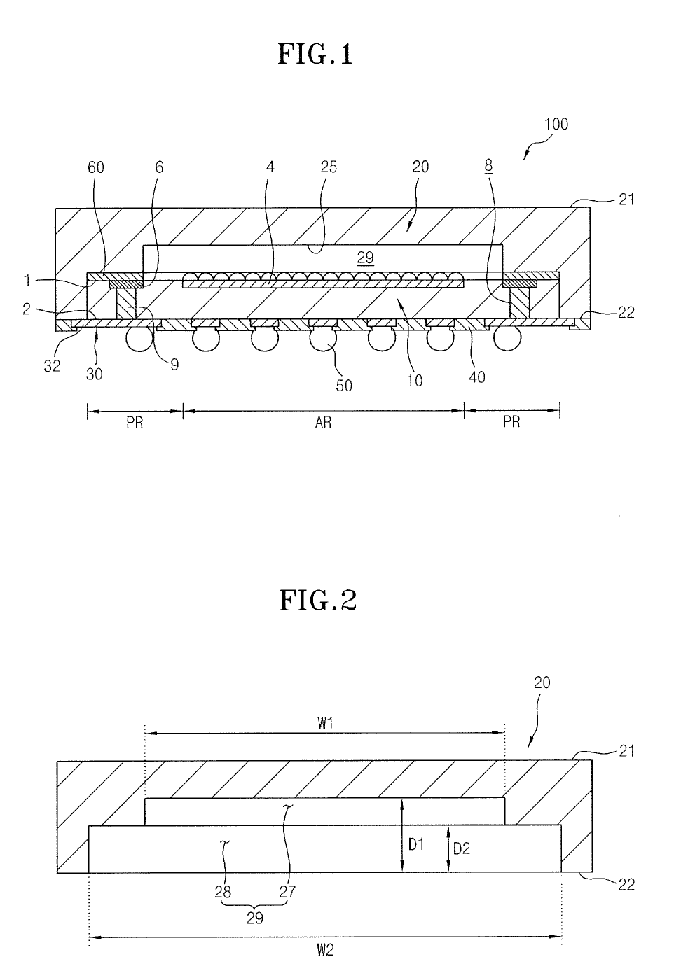

FIG. 1 is a cross-sectional view showing an image sensor module in accordance with an embodiment of the present invention.

Referring to FIG. 1, an image sensor module 100 includes a semiconductor chip 10, a transparent substrate 20, and metal lines 30.

In an embodiment, the semiconductor chip 10 has, for example, the shape of a plate with a small thickness. The semiconductor chip 10 has an upper surface 1 and a lower surface 2 facing away from the upper surface 1. An image sensor region AR is defined on the center portion of the semiconductor chip 10, and a peripheral region PR is defined in a band-like shape along the periphery of the image sensor region AR. In an embodiment, the image sensor region AR can have a quadrangular sectional shape when viewed from the top of the semiconductor chip 10.

The semiconductor chip 10 includes image sensors 4, pads 6, through-holes 8, and through-electrodes 9.

The image sensors 4 are disposed in the image sensor region AR on the upper surface 1 of the semiconductor chip 10.

The image sensors 4 include a plurality of photodiodes (not shown), color filters (not shown) disposed on the respective photodiodes, microlenses (not shown) disposed on the respective color filters, and a driving unit (not shown) connected to the photodiodes and including a plurality of driving transistors (not shown).

The pads 6 are disposed along the peripheral region PR on the upper surface 1 of the semiconductor chip 10 and are electrically connected to the driving unit.

The through-holes 8 are arranged in the peripheral region PR of the semiconductor chip 10 and extend from the lower surface 2 of the semiconductor chip 10 to the pads to allow the pads 6 to be exposed by the corresponding through-holes 8.

The through-electrodes 9 are formed so as to fill the through-holes 8, and due to this fact, are electrically connected with the pads 6. In an embodiment, the through-electrodes 9 may contain, for example, copper.

FIG. 2 is a cross-sectional view showing an embodiment of the transparent substrate shown in FIG. 1.

Referring to FIG. 2, the transparent substrate 20 has the configuration of a plate having a front surface 21 and a rear surface 22 facing away from the front surface 21.

Examples of substrates capable of being used as the transparent substrate 20 include, but are not limited to, a transparent glass substrate, a transparent quartz substrate, and a transparent synthetic resin substrate. In an embodiment, the transparent substrate 20 comprises a transparent glass substrate.

The transparent substrate 20 has a groove 29 defined from the rear surface 22 toward the front surface 21. In an embodiment, the groove 29 of the transparent substrate 20 includes a first groove 27 and a second groove 28.

The first groove 27 is defined from the rear surface 22 toward the front surface 21 of the transparent substrate 20, and has a first width W1 and a first depth D1. The first groove 27 has a size that accommodates the image sensor region AR of the semiconductor chip 10.

The second groove 28 is defined from the rear surface 22 toward the front surface 21 of the transparent substrate 20, and has a second width W2 wider than the first width W1 and a second depth D2 shallower than the first depth D1. The second groove 28 has a size appropriate for receiving the semiconductor chip 10.

In the embodiment shown in FIG. 1, the semiconductor chip 10 is coupled to the transparent substrate 20 in the second groove 28. The image sensors 4 of the semiconductor chip 10 are arranged to face an inner surface 25 of the transparent substrate 20 which is formed as a result of the groove and forms an outer boundary of the first groove 27. The first and second grooves 27, 28 allow the image sensors 4 to be spaced apart from the inner surface 25 by a predetermined distance.

In the embodiment shown in FIG. 1, the semiconductor chip 10 is received in the groove 29. An adhesive member 60 is interposed between the upper surface 1 of the semiconductor chip and the transparent substrate 20. The adhesive member 60 may comprise, for example, a double-sided adhesive tape or an adhesive.

In an embodiment, the rear surface 22 of the transparent substrate 20 and the lower surface 2 of the semiconductor chip 10 are substantially flush with each other. While the rear surface 22 of the transparent substrate 20 in the embodiment shown in FIG. 1 is illustrated as being flush with the lower surface 2 of the semiconductor chip 10 are flush with each other, it can be envisaged that alternatively the rear surface 22 of the transparent substrate 20 and the lower surface 2 of the semiconductor chip 10 are not flush with each other.

Referring again to FIG. 1, the metal lines 30 are disposed on the lower surface 2 of the semiconductor chip 10. Portions of the metal lines 30 are electrically connected to the ends of the through-electrodes 9 of the semiconductor chip 10.

In the case in which the metal lines 30 are disposed only on the lower surface 2 of the semiconductor chip 10, which has a very small area; it may be difficult to arrange solder balls to be electrically connected to the metal lines in accordance with the regulations of JEDEC (Joint Electron Device Engineering Council). In order to cope with this problem, in an embodiment, the metal lines 30 can further include extensions 32 which extend from the lower surface 2 of the semiconductor chip 10 onto the rear surface 22 of the transparent substrate 20. Forming the extensions 32 is this manner allows for an arrangement of solder balls electrically connected to the metal lines 30 that meets the established regulations of JEDEC. Examples of materials capable of being used for forming the metal lines 30 include, but are not limited to, copper, aluminum, gold, and silver.

A solder resist pattern 40, which has openings for exposing portions of the metal lines 30, is formed on the lower surface 2 of the semiconductor chip 10 and the rear surface 22 of the transparent substrate 20, on which the metal lines 30 are formed.

Conductive balls 50 such as solder balls are attached to the exposed portions of the metal lines 30.

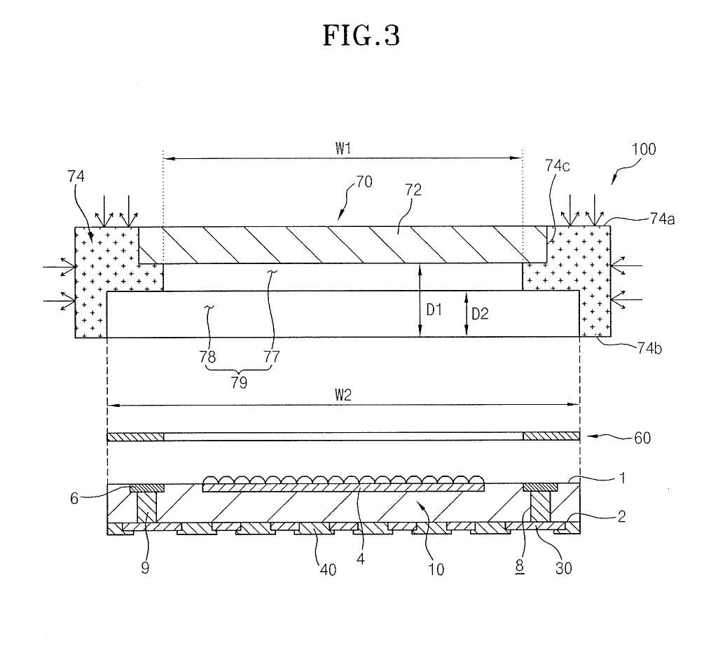

FIG. 3 is a cross-sectional view showing an image sensor module in accordance with another embodiment of the present invention. The image sensor module shown in FIG. 3 is similar to the image sensor module described above with reference to FIG. 1, except the structure of the transparent module 70. Therefore, descriptions of the same component parts will be omitted for brevity, and the same technical terms and the same reference numerals will be used to refer to the same or like component parts.

Referring to FIG. 3, an image sensor module 100 includes a semiconductor chip 10, a transparent substrate 70, and metal lines 30.

The transparent substrate 70 has a transparent member 72 and a housing member 74. The housing member 74 functions to fasten the transparent member 72.

The transparent member 72 has a width that is greater than the size occupied by the image sensors 4 of the semiconductor chip 10. In an embodiment, the transparent member 72 has a plate-like configuration and contains a transparent substance capable of transmitting light. The transparent member 72 may comprise, for example, a transparent glass substrate, a transparent quartz substrate, and a transparent synthetic resin substrate.

In an embodiment, the housing member 74 has the substantial configuration of a cylinder which is open at the front and rear ends thereof. The housing member 74 has a front surface 74a and a rear surface 74b facing away from the front surface 74a.

A coupling groove 74c for coupling the transparent member 72 to the housing member 74 is defined on the front surface 74a of the housing member 74.

The housing member 74 also has a groove 79 which is defined from the rear surface 74b of the housing member 74 toward the front surface 74a. In an embodiment, the groove 79 of the housing member 74 includes a first groove 77 and a second groove 78.

The first groove 77 is defined from the rear surface 74b toward the front surface 74a of the housing member 74, and has a first width W1 and a first depth D1. The first groove 77 has a size that accommodates the image sensor region AR of the semiconductor chip 10.

The second groove 78 is defined from the rear surface 74b toward the front surface 74a of the housing member 74, and has a second width W2 wider than the first width W1 and a second depth D2 shallower than the first depth D1. The second groove 78 has a size appropriate for receiving the semiconductor chip 10.

In an embodiment, the housing member 74 may contain, for example, an opaque substance which absorbs or intercepts light. In the event that the housing member 74 contains an opaque substance, as the light having passed through the transparent member 72 of the transparent substrate 70 is properly incident on the image sensors 4, the quality of an image produced from the image sensors 4 can be improved.

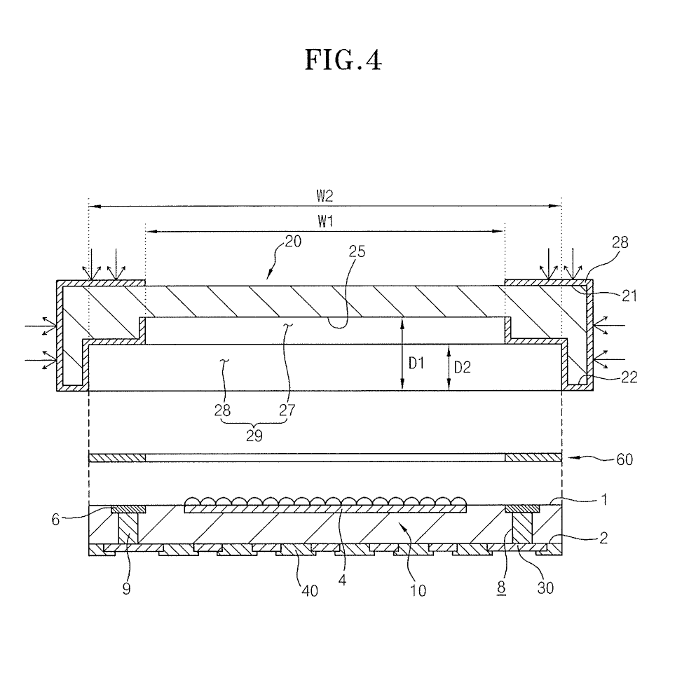

FIG. 4 is a cross-sectional view showing an image sensor module in accordance with another embodiment of the present invention. The image sensor module shown in FIG. 4 is similar to the image sensor module described above with reference to FIG. 1, except a light intercepting member. Therefore, descriptions of the same component parts will be omitted for brevity, and the same technical terms and the same reference numerals will be used to refer to the same or like component parts.

Referring to FIG. 4, an image sensor module 100 includes a semiconductor chip 10, a transparent substrate 20 having a light intercepting member 28, and metal lines 30.

The light intercepting member 28 covers the portion of the transparent substrate 20 in the peripheral region. The light intercepting member covers portions of the transparent substrate outside of the area where it is desired that the light be incident on image sensors so that light incident on the peripheral portion of the transparent substrate 20 outside the image sensors 4 can be intercepted, whereby it is possible to improve the quality of an image produced from the image sensors 4.

The light intercepting member 28 may comprise, for example, a light intercepting tape, a light intercepting pigment or a light intercepting ink, which are all capable of intercepting or absorbing light.

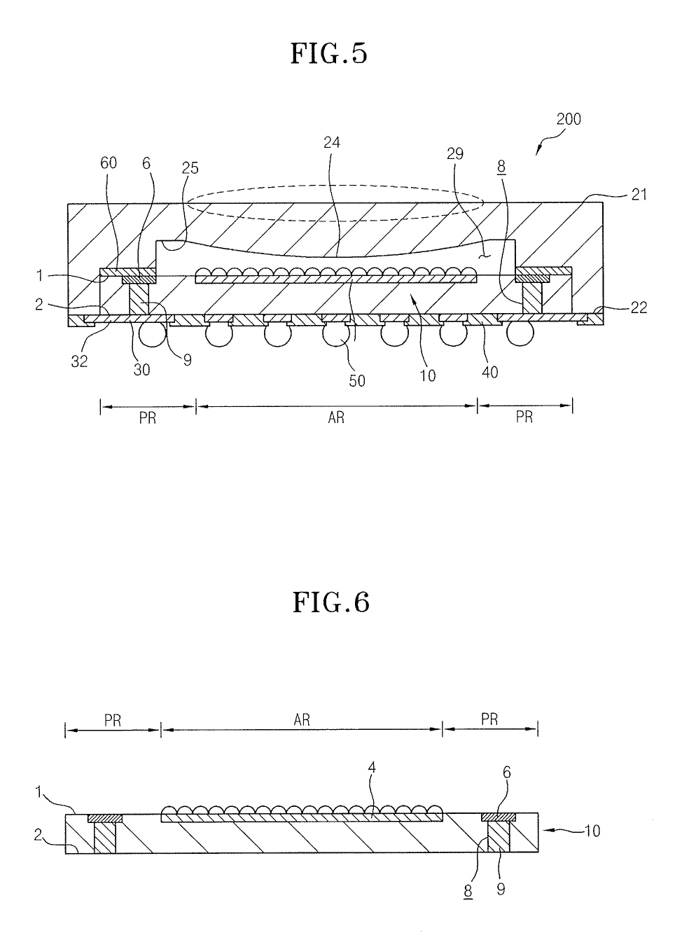

FIG. 5 is a cross-sectional view showing an image sensor module in accordance with another embodiment of the present invention. The image sensor module shown in FIG. 5 is similar to the image sensor module described above with reference to FIG. 1, except a lens part of a transparent substrate. Therefore, descriptions for the same component parts will be omitted for brevity, and the same technical terms and the same reference numerals will be used to refer to the same or like component parts.

Referring to FIG. 5, an image sensor module 100 includes a semiconductor chip 10, a transparent substrate 20 having a lens part 24, and metal lines 30.

The lens part 24 functions to change the nature of the light incident thereon from outside of the transparent substrate 20 and is formed on the inner surface 25 of the transparent substrate 20. In an embodiment, the lens part 24 can comprise a convex lens formed on the inner surface 25 of the transparent substrate 20 to be convex from the inner surface 25 toward the image sensors 4. Alternatively, the lens part 24 can comprise a concave lens formed on the inner surface 25 of the transparent substrate 20 to be concave from the inner surface 25 toward the front surface 21 of the transparent substrate 20 which faces away from the inner surface 25.

Still alternatively, a lens part may be formed on the front surface 21 of the transparent substrate 20 facing away from the inner surface 25, in the shape of a convex lens or a concave lens.

FIGS. 6 through 12 are cross-sectional views showing a method for manufacturing an image sensor module in accordance with another embodiment of the present invention.

Referring to FIG. 6, in an embodiment, when manufacture an image sensor module, a semiconductor chip 10 is manufactured.

In order to manufacture the semiconductor chip 10, semiconductor device manufacturing processes are conducted for a wafer (not shown). The result of these processes is a plurality of semiconductor chips (not shown) formed on the wafer. The semiconductor chips formed on the wafer are sorted into good quality semiconductor chips and bad quality semiconductor chips through an EDS (electric die sorting) process. Then, the good and bad quality semiconductor chips formed on the wafer are individualized by a sawing process, and the good quality semiconductor chips are selected among the good and bad quality semiconductor chips.

The semiconductor chip 10 of FIG. 6, which is determined during sorting as being a good quality semiconductor chip, has, for example, a thin plate-like configuration. The semiconductor chip 10 has an upper surface 1 and a lower surface 2 facing away from the upper surface 1.

An image sensor region and a peripheral region are defined for the semiconductor chip. In an embodiment, the center portion of the semiconductor chip 10 is defined as the image sensor region AR, and the periphery of the image sensor region AR is defined as the peripheral region PR. In an embodiment, the image sensor region AR can have a quadrangular cross-sectional shape when viewed from the top of the semiconductor chip 10.

Image sensors 4 having photodiodes (not shown), color filers (not shown), microlenses (not shown) and a driving unit (not shown) are formed in the image sensor region AR, and pads 6 are formed in the peripheral region PR so as to be electrically connected the image sensors 4.

After the semiconductor chip 10 is manufactured, through-holes 8 are defined in a direction facing from the lower surface 2 toward the upper surface 1 of the semiconductor chip 10. The through-holes 8 are defined at positions corresponding to the pads 6 so that surfaces of the pads 6 are exposed through the through-holes 8. The through-holes 8 can be defined, for example, through an etching process, a drilling process, or a laser drilling process. Through-electrodes 9 are filled in the through-holes 8 so as to be electrically connected to the pads 6. In an embodiment, the through holes may contain copper formed through a deposition technique.

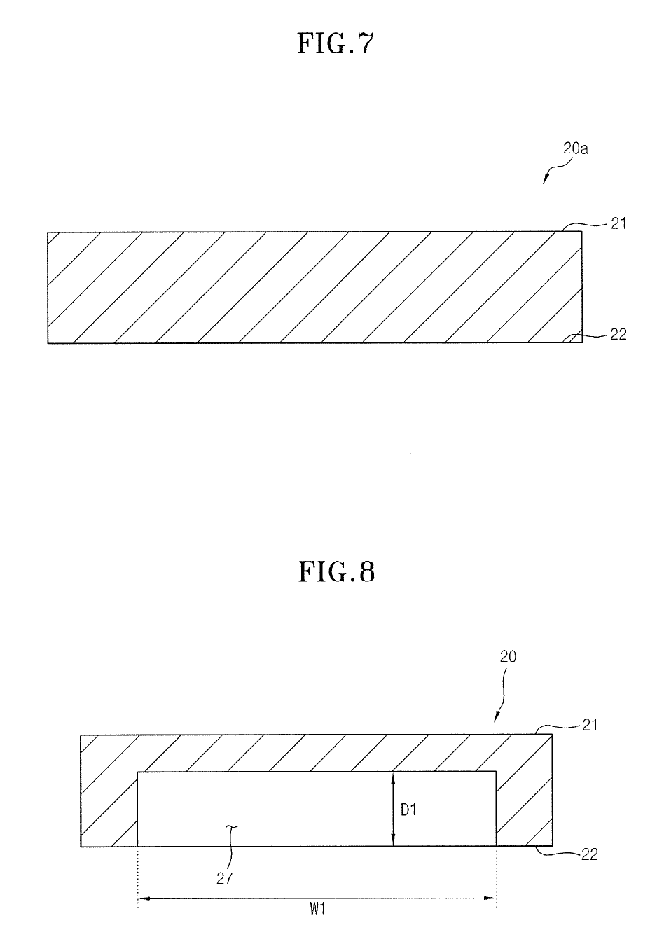

Referring to FIG. 7, a preliminary transparent substrate 20a is first manufactured in order to manufacture a transparent substrate for covering the semiconductor chip 10. In an embodiment, the preliminary transparent substrate 20a has the configuration of a plate having a front surface 21 and a rear surface 22 facing away from the front surface 21.

Examples of substrates capable of being used as the preliminary transparent substrate 20a include a transparent glass substrate, a transparent quartz substrate, and a transparent synthetic resin substrate. In an embodiment, the preliminary transparent substrate 20a comprises a transparent glass substrate.

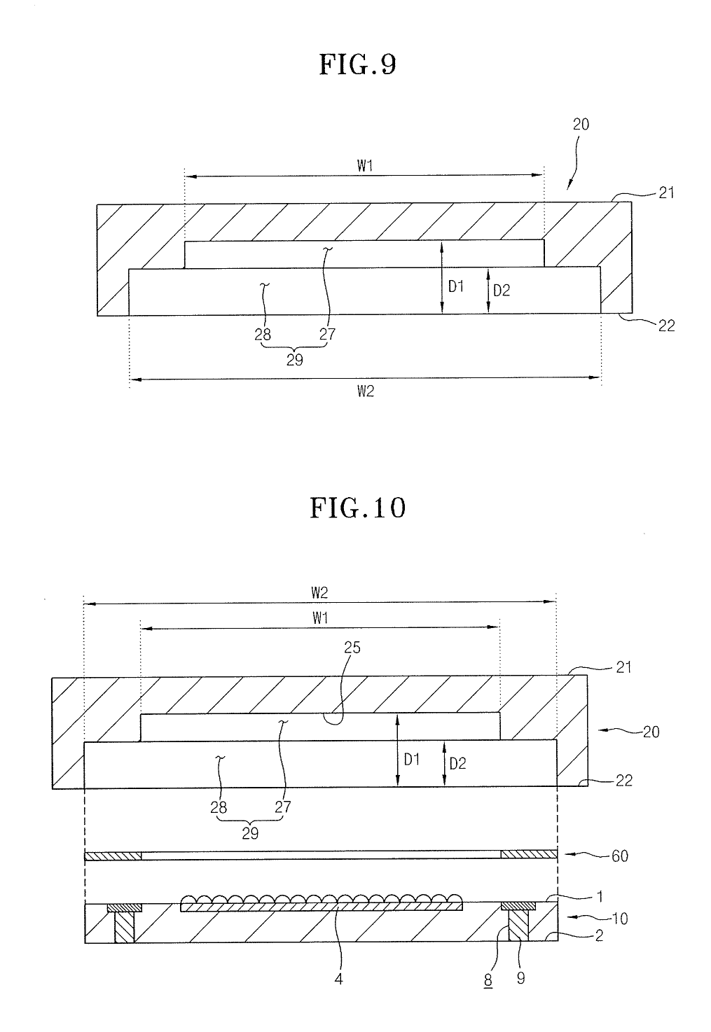

Referring to FIGS. 8 and 9, after the preliminary transparent substrate 20a is formed, a groove 29 is defined on the rear surface 22 of the preliminary transparent substrate 20a, by which a transparent substrate 20 is prepared. The groove 29 is defined in a direction facing from the rear surface 22 toward the front surface 21 of the preliminary transparent substrate 20a.

In an embodiment, the groove 29 formed in the preliminary transparent substrate 20a may be defined through an etching process, for example, using an etchant or plasma. Alternatively, the preliminary transparent substrate 20a having the groove 29 can be formed through an extrusion process in which substance to form the preliminary transparent substrate 20a is melted and poured into a mold. Alternatively, the groove 29 formed in the preliminary transparent substrate 20a can be defined through a stamping process implemented after heating the preliminary transparent substrate 20a to decrease its hardness.

In an embodiment, the groove 29 formed in the preliminary transparent substrate 20a has a first groove 27 and a second groove 28.

Referring to FIG. 8, the first groove 27 is first defined in the preliminary transparent substrate 20a. The first groove 27 is defined from the rear surface 22 toward the front surface 21 of the preliminary transparent substrate 20a, and has a first width W1 and a first depth D1. The first groove 27 has a size that accommodates the image sensor region AR of the semiconductor chip 10.

Referring to FIG. 9, after the first groove 27 is defined, the second groove 28 is defined from the rear surface 22 toward the front surface 21 of the transparent substrate 20, and has a second width W2 wider than the first width W1 and a second depth D2 shallower than the first depth D1. The second groove 28 has a size appropriate for receiving the semiconductor chip 10.

Referring to FIG. 10, the semiconductor chip 10 is received in the second groove 28 and coupled to the transparent substrate 20. The image sensors 4 of the semiconductor chip 10 are arranged so as to face an inner surface 25 of the transparent substrate 20 formed as a result of defining the first groove 27. The first groove 27 have a width less than but a depth greater than that of the second groove 28 allows the image sensors 4 to be spaced apart from the inner surface 25 by a predetermined distance.

In an embodiment, an adhesive member 60 is interposed between the upper surface 1 of the semiconductor chip 10 and the transparent substrate 20, for example, between the upper surface 1 of the semiconductor chip and the inner surface of the transparent substrate 20 formed as a result of defining the second groove 28. The adhesive member 60 may comprise, for example, a double-sided adhesive tape or an adhesive.

In the embodiment shown in FIG. 10, the size, shape, and arrangement of the transparent substrate 20 and the semiconductor chip 10 is such that the rear surface 22 of the transparent substrate 20 and the lower surface 2 of the semiconductor chip 10 are substantially flush with each other. However, it can be envisaged that alternatively the rear surface 22 of the transparent substrate 20 and the lower surface 2 of the semiconductor chip 10 are not flush with each other.

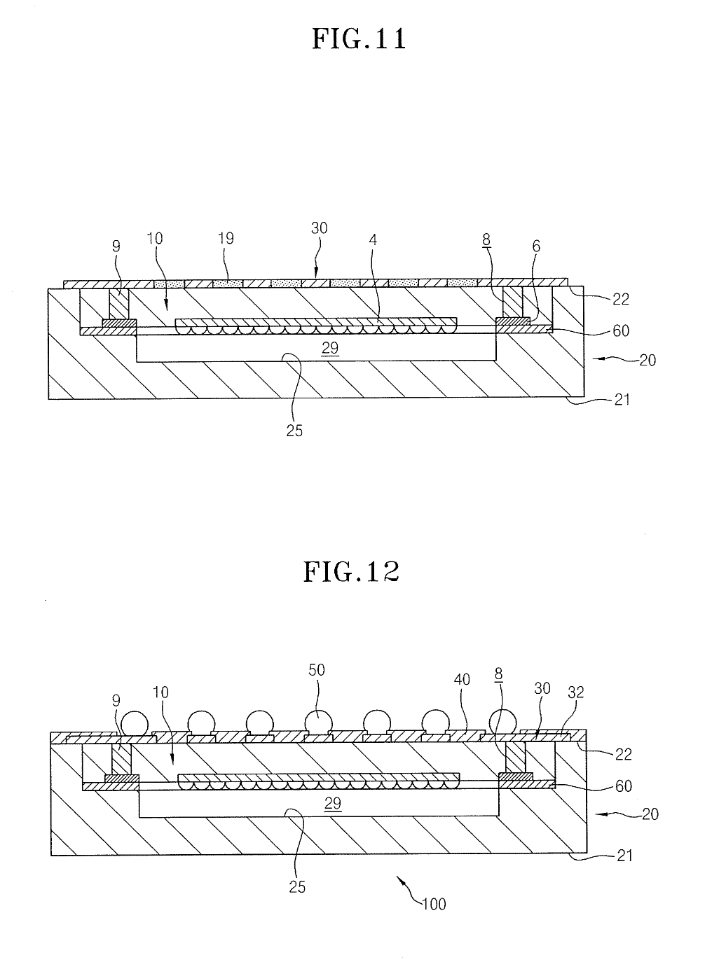

Referring to FIG. 11, metal lines 30 are disposed on the lower surface 2 of the semiconductor chip 10. In order to form the metal lines 30, a photoresist pattern 19 having openings for forming the metal lines 30 is formed on the lower surface 2 of the semiconductor chip 10. The metal lines 30 are formed in the openings of the photoresist pattern 19 through, for example, a plating process, a sputtering process, and so forth. Then, the photoresist pattern 19 is removed from the lower surface 2 of the semiconductor chip 10. In an embodiment, the metal lines 30 are filled in the through-holes 8 of the semiconductor chip 10 and are formed on the lower surface 2 of the semiconductor chip 10. The through-holes 8 may, for example, be formed at the time of manufacturing the semiconductor chip as shown in FIG. 10, or alternatively, at the time of forming the metal lines 30. In an embodiment, the metal lines 30 formed on the lower surface 2 of the semiconductor chip 10 can further include extensions 32 which extend onto the rear surface 22 of the transparent substrate 20.

In an embodiment, examples of materials capable of being used for forming the metal lines 30 include copper, aluminum, gold, and silver.

Referring to FIG. 12, a solder resist pattern 40, which has openings for exposing portions of the metal lines 30, is formed on the lower surface 2 of the semiconductor chip 10 and the rear surface 22 of the transparent substrate 20, on which the metal lines 30 are formed. Conductive balls 50 such as solder balls are attached to the exposed portions of the metal lines 30 to form the image sensor module 100.

While it was described with reference to FIGS. 6-12 that the groove 29 is defined by processing the rear surface 22 of the transparent substrate 20 as shown in FIG. 9; alternatively, it is of course conceivable that, as shown in FIG. 3, the transparent member 72 and the housing member 74 are manufactured and then the transparent member 72 is coupled to the inner surface of the housing member 74. At this time, it is preferred that the transparent member 72 be formed of transparent substance and the housing member 74 contain an opaque substance for absorbing or intercepting light. Meanwhile, it can also be envisaged that, as shown in FIG. 4, the light intercepting member 28 is disposed on the peripheral portion of the transparent substrate 20 which excludes the portion of the transparent substrate 20 corresponding to the image sensors 4.

While it was illustrated and described with reference to FIGS. 6-12 that the inner surface 25 of the transparent substrate 20, which is formed due to defining of the groove 29, is flat; alternatively, it is conceivable that, as shown in FIG. 5, a lens part 24 having the shape of a concave lens or a convex lens can be formed on the inner surface 25 and/or the outer surface, which is opposite to the inner surface 25, of the transparent substrate 20 while manufacturing the transparent substrate 20.

Further, while the transparent substrate 70 including the transparent member 72 and the housing member 74 as shown in FIG. 3 was illustrated and described, a lens part having the shape of a concave lens or a convex lens may be formed on the transparent member 72.

Moreover, while it was illustrated and described that the light intercepting member 28 is formed on the transparent substrate 20 having the groove 29 as shown in FIG. 4, a lens part having the shape of a concave lens or a convex lens may be formed on the inner surface 25 and/or the outer surface, opposite to the inner surface 25, of the transparent substrate 20 while manufacturing the transparent substrate 20.

As is apparent from the above description, in the present invention, since an image sensor module process is conducted by sorting good quality semiconductor chips, the manufacturing cost for manufacturing an image sensor module can be significantly reduced, and the performance of the image sensor module can be considerably improved.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A method for manufacturing an image sensor module, comprising the steps of:
providing a semiconductor chip comprising: image sensors formed in an image sensor region, pads electrically connected to the image sensors and disposed in a peripheral region defined along a periphery of the image sensor region, and through-electrodes electrically connected to the pads;
providing a transparent substrate having a groove defined so as to form an inner surface;
coupling the transparent substrate and the semiconductor chip such that the inner surface of the transparent substrate and the image sensors face each other; and
forming metal lines on a lower surface of the semiconductor chip electrically connected to the through-electrodes.

2. The method according to claim 1, wherein the step of providing the semiconductor chip includes manufacturing the semiconductor chip, and manufacturing the semiconductor chip comprises:
forming semiconductor chips on a wafer;
testing the semiconductor chips and sorting good and bad quality semiconductor chips; and
individualizing the semiconductor chips from the wafer and selecting a good quality semiconductor chip to be provided as the semiconductor chip.

3. The method according to claim 1, wherein the step of providing the transparent substrate includes forming the transparent substrate, and forming the transparent substrate comprises:
defining a first groove having a first area and a first depth that correspond to those of the image sensor region, on the transparent substrate; and
defining a second groove having a second area that corresponds to an area of the semiconductor chip and a second depth that is shallower than the first depth, on the transparent substrate.

4. The method according to claim 3, wherein the first and second grooves are defined through any one of an etching process for etching the transparent substrate, an extrusion process for extruding melted transparent substance using a mold, and a stamping process for stamping a flowable transparent substance.

5. The method according to claim 1, wherein the step of providing the transparent substrate comprises:
preparing a transparent member which corresponds to the image sensor region; and
fastening the transparent member to an inner surface of a housing member.

6. The method according to claim 5, wherein the housing member is formed of light intercepting substance for intercepting light.

7. The method according to claim 1, wherein the step of providing the transparent substrate includes forming the transparent substrate, and forming the transparent substrate comprises:
forming a light intercepting member in the peripheral region to intercept light incident on the peripheral region of the transparent substrate.

8. The method according to claim 1, wherein the transparent substrate and the semiconductor chip are coupled such that a rear surface of the transparent substrate and the lower surface of the semiconductor chip are flush with each other.

9. The method according to claim 1, wherein the step of forming the metal lines comprises:
extending portions of the wiring lines from the lower surface of the semiconductor chip onto the rear surface of the transparent substrate.

10. The method according to claim 1, wherein the step of providing the transparent substrate comprises the step of:
forming a lens part on at least one of the inner surface and a front surface, which is opposite to the inner surface, of the transparent substrate.

11. The method according to claim 1, further comprising the step of:
forming a lens part on at least one of the inner surface and a front surface, which is opposite to the inner surface, of the transparent substrate.
